(19) United States
(12) Patent Application Publication
(10) Pub. No.: US 2018/0083179 A1
(43) Pub. Date: Mar. 22, 2018

(54) THERMOELECTRIC CONVERSION DEVICE

(71) Applicant: SHOWA DENKO K.K., Tokyo (JP)

(72) Inventors: Yasutaka YOSHIDA, Chichibu-shi (JP); Akifumi MURAOKA, Chichibu-shi (JP)

(73) Assignee: SHOWA DENKO K.K., Tokyo (JP)

(21) Appl. No.: 15/706,800

(22) Filed: Sep. 18, 2017

(30) Foreign Application Priority Data
Sep. 20, 2016 (JP) 2016-183363

(51) Int. Cl. H01L 35/32; F25B 21/02; H01L 23/38

(52) U.S. Cl. CPC H01L 35/32; H01L 23/38; F25B 21/02

(57) ABSTRACT

A thermoelectric conversion device includes: a thermoelectric conversion unit that includes thermoelectric conversion elements converting heat caused by temperature difference between a high-temperature side and a low-temperature side into electricity; a base unit that is loaded with the thermoelectric conversion unit to face the low-temperature side of the thermoelectric conversion unit; a lid unit that covers the thermoelectric conversion unit to face the high-temperature side of the thermoelectric conversion unit; a press ring that is provided over an entire circumference of outside of periphery of the thermoelectric conversion unit and sandwiches the brim portion of the lid unit between thereof and the base unit; and plural screws that position the lid unit with respect to the base unit and the thermoelectric conversion unit between the base unit and the lid unit by fixing the press ring to the base unit via the brim portion of the lid unit.

### CROSS REFERENCE TO RELATED APPLICATIONS

This application is based on and claims priority under 35 USC § 119 from Japanese Patent Application No. 2016-183363 filed Sep. 20, 2016.

### BACKGROUND

### Technical Field

The present invention relates to a thermoelectric conversion device.

### Related Art

Conventionally, there has been known a thermoelectric conversion device that converts thermal energy into electric energy by thermoelectric conversion elements using thermoelectric semiconductors exerting a thermoelectric effect, such as the Thomson effect, the Peltier effect or the Seebeck effect.

For example, to suppress oxidation of thermoelectric conversion elements due to temperature rise, the thermoelectric conversion device of this type adopts, in many cases, a configuration in which a thermoelectric conversion unit including the thermoelectric conversion elements is contained in a container (housing) having airtightness.

As such a thermoelectric conversion device, the one has been known in which a thermoelectric conversion circuit board including plural P-type semiconductor elements and N-type semiconductor elements connected in series and arranged in a two-dimensional matrix is sandwiched between two heat exchange plates, an O-ring is provided to an entire circumference outside of an outer circumference of the thermoelectric conversion circuit board between these two heat exchange plates, and these two heat exchange plates are fixed by bolts tightening thereof in directions approaching each other at plural locations, such as outer edge portions, a center portion and so forth (refer to Japanese Patent Application Laid-Open Publication No. 2002-147888).

However, when a configuration in which the thermoelectric conversion unit including the thermoelectric conversion elements is sandwiched by two fixing members and these two fixing members are directly fixed by use of plural bolts or the like is adopted, a load applied to the fixing members differs between portions used in fixing by the bolts or the like and portions not used in fixing. Then, there was a possibility that a load applied from the two fixing members to the thermoelectric conversion unit varied, and the thermoelectric conversion elements provided with a large load are damaged.

An object of the present invention is to suppress damage of the thermoelectric conversion elements due to such an imbalance in applied load.

### SUMMARY

A thermoelectric conversion device according to an aspect of the present invention includes: a thermoelectric conversion unit that includes thermoelectric conversion elements converting thermal energy caused by temperature difference between a high-temperature side and a low-temperature side of the thermoelectric conversion unit into electric energy; a loading member that is loaded with the low-temperature side of the thermoelectric conversion unit; a covering member that covers the high-temperature side of the thermoelectric conversion unit loaded on the loading member; a sandwiching member that is provided over an entire circumference of an outside of periphery of the thermoelectric conversion unit loaded on the loading member and sandwiches the covering member with the loading member; and a positioning member that positions the covering member with respect to the loading member and sandwiches the thermoelectric conversion unit between the loading member and the covering member to position the thermoelectric conversion unit by fixing the sandwiching member to the loading member.

In such a thermoelectric conversion device, the loading member includes a front surface that is loaded with the thermoelectric conversion unit, a back surface that is an opposite side of the front surface and a side surface positioned between the front surface and the back surface, and the loading member is provided with a through hole, one end of which is provided to the front surface and the other end of which is provided to the side surface, and inside of which an electric wire for extracting current generated in the thermoelectric conversion unit to an outside penetrates, and another through hole, one and the other ends of which are provided to the side surface, and inside of which a liquid for cooling the low-temperature side of the thermoelectric conversion unit passes.

Moreover, when the loading member is provided with plural through holes, in the loading member, the plural through holes are disposed only at one side of the side surface of the loading member as viewed from the other through hole.

Further, the thermoelectric conversion device also includes an airtight member that is provided between the loading member and a portion of the covering member which is sandwiched by the sandwiching member, the airtight member having elasticity and being in contact with the loading member and the covering member over an entire circumference, to increase airtightness of an inner space formed by the loading member and the covering member for containing the thermoelectric conversion unit.

Moreover, the thermoelectric conversion device further includes: a low-temperature side insulation member that is composed of aluminum nitride and disposed between the loading member and the low-temperature side of the thermoelectric conversion unit to electrically insulate the loading member from the thermoelectric conversion unit; and a high-temperature side insulation member that is composed of aluminum oxide and disposed between the covering member and the high-temperature side of the thermoelectric conversion unit to electrically insulate the covering member from the thermoelectric conversion unit.

Further, the loading member is composed of an aluminum alloy and the covering member and the sandwiching member are composed of a stainless steel.

On a loading surface in the loading member to be loaded with the thermoelectric conversion unit, plural protruding portions are provided to positions enclosing around the loaded thermoelectric conversion unit.

According to the present invention, it is possible to suppress damage to the thermoelectric conversion elements due to such an imbalance in applied load.

### BRIEF DESCRIPTION OF THE DRAWINGS

An exemplary embodiment of the present invention will be described in detail based on the following figures, wherein:

FIG. 1 is a perspective view showing a schematic configuration of a thermoelectric conversion device to which the exemplary embodiment is applied;

FIG. 2 is an exploded perspective view of the thermoelectric conversion device shown in FIG. 1;

FIG. 3 is a cross-sectional view for illustrating an internal configuration of the thermoelectric conversion device;

FIG. 4 is a top view of a base unit constituting a housing of the thermoelectric conversion device as viewed from above; and

FIG. 5 is a perspective view showing a schematic configuration of a main body of a thermoelectric conversion unit constituting the thermoelectric conversion device.

### DETAILED DESCRIPTION

Hereinafter, an exemplary embodiment according to the present invention will be described in detail with reference to attached drawings.

### [Overall Configuration of Thermoelectric Conversion Device]

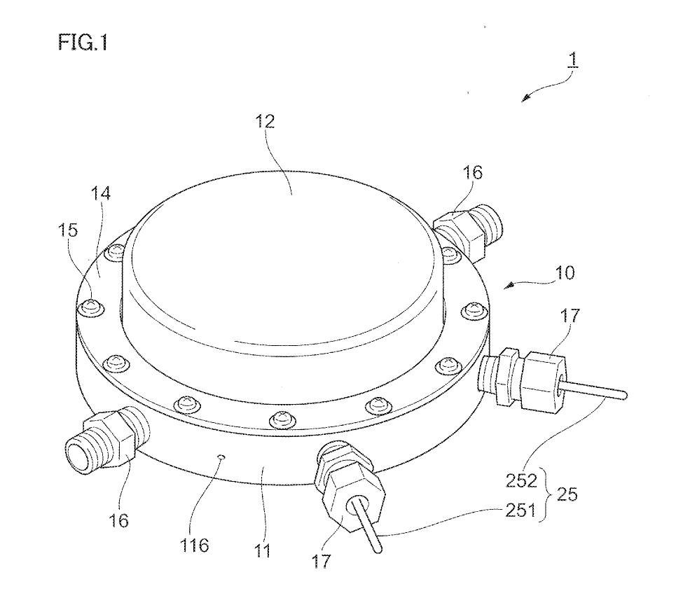

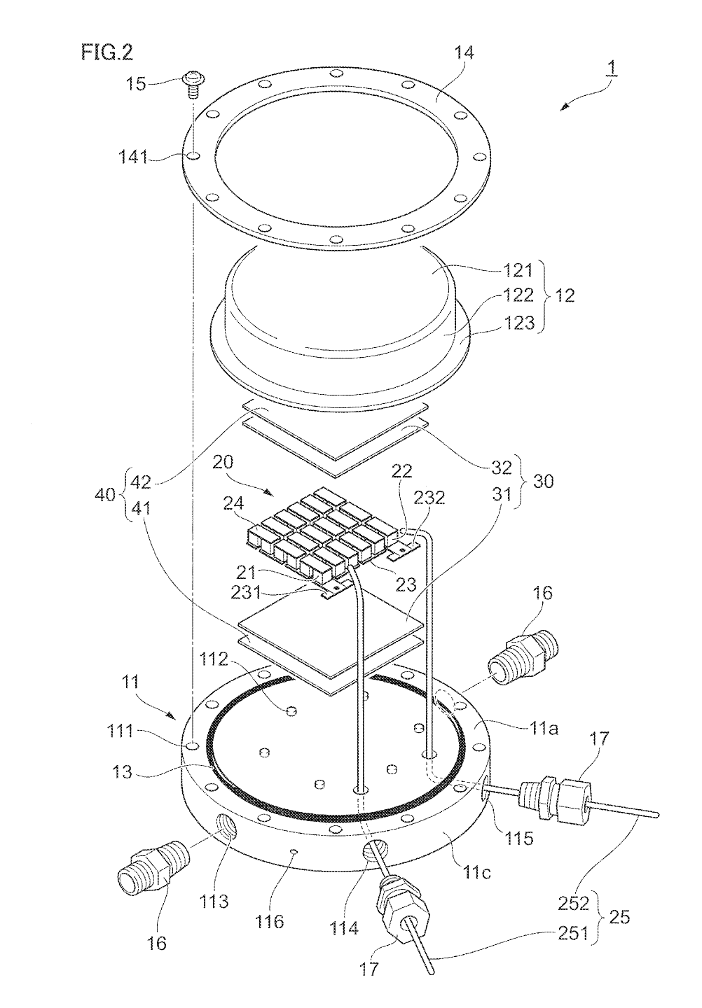

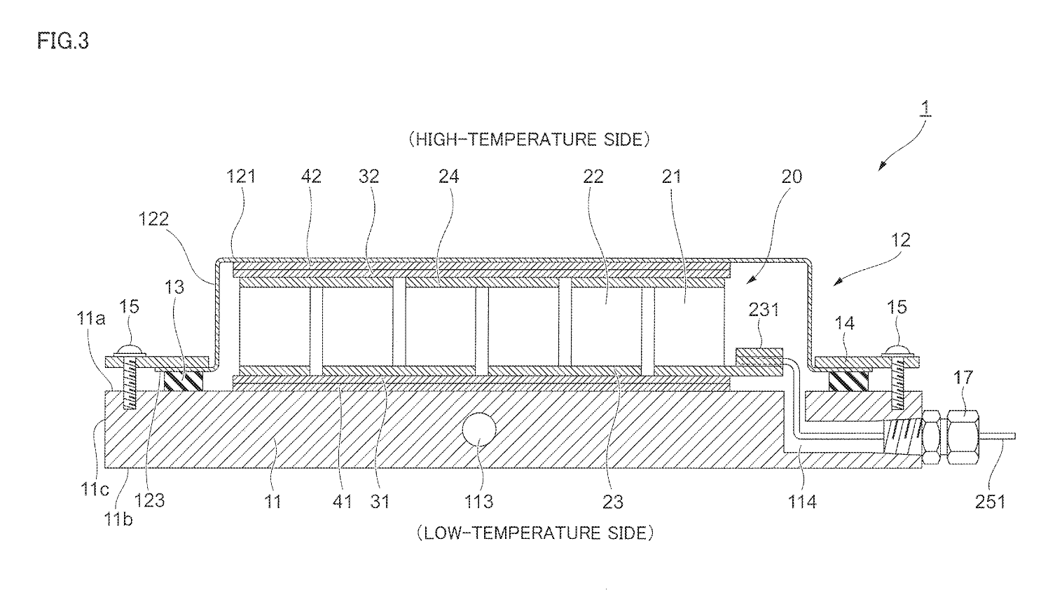

FIG. 1 is a perspective view showing a schematic configuration of a thermoelectric conversion device 1 to which the exemplary embodiment is applied. FIG. 2 is an exploded perspective view of the thermoelectric conversion device 1 shown in FIG. 1. Further, FIG. 3 is a cross-sectional view for illustrating an internal configuration of the thermoelectric conversion device 1.

The thermoelectric conversion device 1 is used for, for example, converting thermal energy generated in a garbage incineration plant or others into electric energy.

The thermoelectric conversion device 1 includes: a housing 10, one surface of which is a high-temperature side that faces or contacts a heat source, such as exhaust gas, and the other surface of which on a backside thereof is a low-temperature side; and a thermoelectric conversion unit 20 that is contained in an inner space of the housing 10 and converts thermal energy, which is caused by a difference in temperature between the high-temperature side and the low-temperature side received via the housing 10, into electric energy. Moreover, the thermoelectric conversion device 1 further includes: an insulation unit 30 that is provided in the inner space of the housing 10 and electrically insulates the thermoelectric conversion unit 20 from the housing 10; and a heat transfer unit 40 that transfers heat (high temperature and low temperature) from the housing 10 to the thermoelectric conversion unit 20 via the insulation unit 30.

A configuration of each part constituting the thermoelectric conversion device 1 will be described.

### [Configuration of Housing]

First, a configuration of the housing 10 will be described.

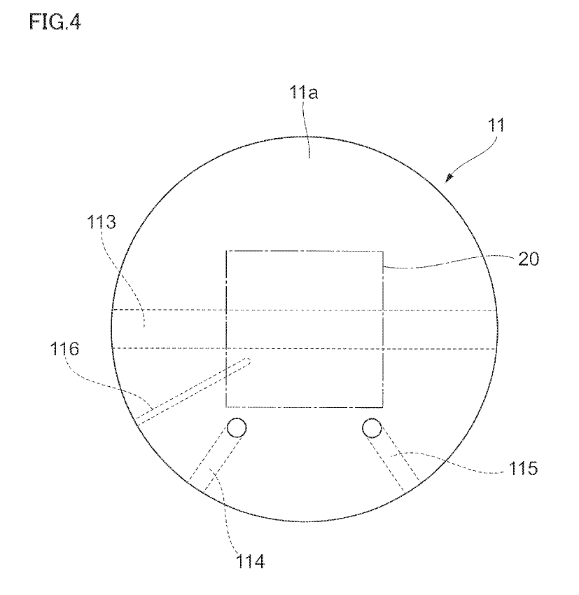

FIG. 4 is a top view of a base unit 11 constituting the housing 10 of the thermoelectric conversion device 1 as viewed from above. Hereinafter, descriptions will be given also with reference to FIG. 4 in addition to FIGS. 1 to 3. Note that, in FIG. 4, descriptions of screw holes 111 and protruding portions 112 to be described later are omitted, and the thermoelectric conversion unit 20 mounted on the base unit 11 is indicated by a long-dot-and-dash line.

The housing 10 includes: the base unit 11 that shows a disc shape and is loaded with the thermoelectric conversion unit 20 on a surface 11a side thereof; and a lid unit 12 that shows a straw-boater-hat shape and covers the thermoelectric conversion unit 20 mounted on the base unit 11.

Moreover, the housing 10 includes: an airtight ring 13 that is disposed on the outside of periphery of the thermoelectric conversion unit 20 between the base unit 11 and the lid unit 12 and increases airtightness of the inner space formed between the base unit 11 and the lid unit 12; and a press ring 14 that presses the lid unit 12 from above the lid unit 12 toward the surface 11a of the base unit 11. Further, the housing 10 includes plural (in this example, twelve pieces screws 15 that perform positioning and fixing of the lid unit 12 with respect to the base unit 11 and positioning and fixing of the thermoelectric conversion unit 20 with respect to the base unit 11 and the lid unit 12 by screwing the press ring 14 against the base unit 11 with a brim portion 123 (to be described in detail later) of the lid unit 12 being interposed between the base unit 11 and the press ring 14.

The thermoelectric conversion device 1 is placed such that the lid unit 12 of the housing 10 is positioned on a heat source side (high-temperature side) and the base unit 11 is positioned on an opposite side of the heat source (low-temperature side). Consequently, in the thermoelectric conversion unit 20 provided to the thermoelectric conversion device 1, the side facing the base unit 11 is the low-temperature side, and the side facing the lid unit 12 is the high-temperature side.

### (Base Unit)

The base unit 11 as an example of a loading member includes: a front surface 11a and a back surface 11b showing a circular shape and having a front-and-back relationship; and a side surface 11c showing a cylindrical shape and being positioned between the front surface 11a and the back surface 11b. Then, as described above, the thermoelectric conversion unit 20 is loaded on the front surface 11a side of the base unit 11.

The base unit 11 of the exemplary embodiment is composed of a material having high thermal conductivity. In this example, the base unit 11 is composed of, of metallic materials having high thermal conductivity, an aluminum alloy capable of weight saving due to low density.

On a periphery side of the base unit 11, the screw holes 111, which are dug from the front surface 11a toward the back surface 11b side and into each of which the screw 15 is entwisted, are provided at 12 locations at regular intervals in the circumferential direction.

Moreover, on the front surface 11a of the base unit 11, the six protruding portions 112 that protrude toward the above in the figure, that is, toward the lid unit 12, are provided on the center side of the plural screw holes 111. Each of the six protruding portions 112 shows a columnar shape and is positioned at each vertex of a hexagon on the front surface 11a of the base unit 11.

Further, the base unit 11 is provided with a linear through hole 113, one end and the other end of which are exposed at the side surface 11c, and which penetrates inside the base unit 11 linearly to pass through below an attaching position of the thermoelectric conversion unit 20. Here, inside of each of both end portions of the linear through hole 113 as an example of another through hole, a female screw is formed.

Still further, the base unit 11 is provided with a first curved through hole 114 and a second curved through hole 115, one end of each of which is exposed at the side surface 11c and the other end of each of which is exposed at the front surface 11a, and which penetrate in an L shape inside the base unit 11. Here, inside of each of end portions on the side surface 11c side of the first curved through hole 114 and the second curved through hole 115 as an example of a through hole, a female screw is formed. Moreover, the end portions on the front surface 11a side of the first curved through hole 114 and the second curved through hole 115 are located closer to the center side than the plural screw holes 111 and outward of the attaching position of the thermoelectric conversion unit 20.

Moreover, the base unit 11 is provided with a non-through hole 116, one end of which is exposed at the side surface 11c, and the other end of which reaches in front of the linear through hole 113 and below the attaching position of the thermoelectric conversion unit 20.

Note that, inside the base unit 11, the linear through hole 113, the first curved through hole 114, the second curved through hole 115 and the non-through hole 116 are not connected with one another. Moreover, in the exemplary embodiment, the linear through hole 113, the first curved through hole 114, the second curved through hole 115, the non-through hole 116 and the twelve screw holes 111 are not connected with one another.

In the base unit 11 of the exemplary embodiment when viewed by taking the linear through hole 113 as a reference, the first curved through hole 114, the second curved through hole 115 and the non-through hole 116 are collectively disposed on one side (on the lower side in FIG. 4). As viewed from the opposite standpoint, in the base unit 11, when viewed by taking the linear through hole 113 as a reference, any hole for exposure is not provided on the side surface 11c on the other side (on the upper side in FIG. 4).

Then, the thermoelectric conversion device 1 includes two water channel joints 16 attached by screwing at the both end portions of the linear through hole 113 provided on the side surface 11c of the base unit 11. Moreover, the thermoelectric conversion device 1 includes two current output terminals 17 attached by screwing at the respective end portions of the first curved through hole 114 and the second curved through hole 115 provided on the side surface 11c of the base unit 11. Note that, when the thermoelectric conversion device 1 is used, a thermocouple (not shown) for measuring temperature is inserted into the non-through hole 116.

### (Lid Unit)

The lid unit 12 as an example of a covering member includes: a ceiling portion 121 showing a disc shape and facing the center portion of the front surface 11a of the base unit 11; a side wall portion 122 showing a cylindrical shape and extending from the periphery of the ceiling portion 121 toward the base unit 11; and the brim portion 123 showing an annular shape and extending from the end portion of the side wall portion 122 on the base unit 11 side toward the outer circumference side. Then, inside a space formed by the ceiling portion 121 and the side wall portion 122, the six protruding portions 112 formed on the front surface 11a of the base unit 11 and the thermoelectric conversion unit 20 disposed inside the six protruding portions 112 are positioned.

Since being exposed to high-temperature environment, the lid unit 12 of the exemplary embodiment is composed of a material having high heat resistance. Though being different depending on purpose of use or the like of the thermoelectric conversion device 1, in the case of the exemplary embodiment, the ceiling portion 121 of the lid unit 12 positioned on the high-temperature side is sometimes heated up to maximum of the order of 800° C. In this example, the lid unit 12 is composed of, of the metallic materials having high heat resistance, a stainless steel having corrosion resistance.

Here, the outer diameter of the brim portion 123 in the lid unit 12 is set smaller than the outer diameter of the base unit 11. To describe more specifically, the outer diameter of the brim portion 123 is set to allow the periphery of the brim portion 123 provided to the lid unit 12 to be positioned inside the plural screw holes 111 provided on the peripheral side of the base unit 11.

Moreover, the inner diameter of the side wall portion 122 in the lid unit 12 is set smaller than the inner diameter of the airtight ring 13 and larger than the outer diameter of each of the thermoelectric conversion unit 20, the insulation unit 30 and the heat transfer unit 40 contained inside thereof.

### (Airtight Ring)

The airtight ring 13 as an example of an airtight member shows an annular shape. The airtight ring 13 is disposed at a position inside the plural screw holes 111 on the front surface 11a of the base unit 11 and facing the lower surface of the brim portion 123 in the lid unit 12. The cross section of the airtight ring 13 shows a rectangular shape.

The airtight ring 13 of the exemplary embodiment is composed of a material having elasticity. In this example, the airtight ring 13 is composed of, of resin materials or rubber materials having elasticity, polytetrafluoroethylene (PTFE) having relatively high heat resistance. The airtight ring 13 is prepared by stamping a sheet made of polytetrafluoroethylene in the annular shape. Other than the above-described polytetrafluoroethylene, the material constituting the airtight ring 13 may be a material having high heat resistance, and fluorine-containing rubber may be used.

Here, the inner diameter of the airtight ring 13 is larger than the inner diameter of the brim portion 123 of the lid unit 12. The outer diameter of the airtight ring 13 is smaller than the outer diameter of the brim portion 123 of the lid unit 12.

### (Press Ring)

The press ring 14 as an example of a sandwiching member shows an annular shape. The press ring 14 is disposed at a position facing the upper surface of the brim portion 123 of the lid unit 12.

The press ring 14 of the exemplary embodiment is composed of a material having high heat resistance. In this example, the press ring 14 is composed of a stainless steel.

The inner diameter of the press ring 14 is larger than the outer diameter of the side wall portion 122 and smaller than the outer diameter of the brim portion 123, which are provided to the lid unit 12. Moreover, the outer diameter of the press ring 14 is substantially the same as the outer diameter of the base unit 11.

In the press ring 14, opening portions 141 penetrating from the upper surface to the lower surface are provided at twelve locations at regular intervals in the circumferential direction. Here, the twelve opening portions 141 provided to the press ring 14 are in a positional relationship to overlap with the twelve respective screw holes 111 provided to the base unit 11.

### (Screws)

The twelve pieces screws 15 as an example of a positioning member are entwisted into the respective screw holes 111 provided to the base unit 11 via the opening portions 141 provided to the press ring 14.

The screw 15 of the exemplary embodiment is composed of, for example, a stainless steel.

### (Water Channel Joints)

Each of the two water channel joints 16 is a hollow member having a male screw and a nut portion formed on the outer circumference surface thereof and a through hole formed inside thereof. The water channel joints 16 are composed of a metallic material, and the male screw provided to one end side of each is entwisted into the female screw of the linear through hole 113 provided to the side surface 11c of the base unit 11, to be fixed. Then, when the thermoelectric conversion device 1 is used, water for cooling the low-temperature side of the thermoelectric conversion unit 20 (cooling water) is supplied to the linear through hole 113 provided to the base unit 11 via the two water channel joints 16.

### (Current Output Terminal)

Each of the two current output terminals 17 is a member including: a male screw and a nut portion formed on the outer circumference surface thereof; a through hole formed inside thereof; and a cylindrical elastic member having an insulation property and being composed of an elastic body, such as rubber, disposed therein. The main bodies of the current output terminals 17 are composed of a metallic material, and the male screws provided to one end side thereof are entwisted into the respective female screws of the first curved through hole 114 and the second curved through hole 115 provided to the side surface 11c of the base unit 11, to be fixed. Then, an output electric wire 25 provided to the thermoelectric conversion unit 20 is attached to these two current output terminals 17, which will be described in detail later.

### [Configuration of Insulation Unit]

Next, a configuration of the insulation unit 30 will be described.

The insulation unit 30 includes a low-temperature side insulation member 31 and a high-temperature side insulation member 32, each of which is made of a plate material showing a rectangular shape. Of these, the low-temperature side insulation member 31 is disposed between the front surface 11a of the base unit 11 and the low-temperature side of the thermoelectric conversion unit 20. On the other hand, the high-temperature side insulation member 32 is disposed between the high-temperature side of the thermoelectric conversion unit 20 and the ceiling portion 121 of the lid unit 12.

The low-temperature side insulation member 31 is composed of aluminum nitride.

The low-temperature side insulation member 31 of the exemplary embodiment is set in a size slightly larger than the thermoelectric conversion unit 20. However, the size of the low-temperature side insulation member 31 is set to be slightly smaller than a region enclosed by the six protruding portions 112 provided to the front surface 11a of the base unit 11. Here, it is desirable that the length of one side of the low-temperature side insulation member 31 is longer than the thermoelectric conversion unit 20 by 1 mm to 5 mm. Within the above range, a short circuit can be prevented if the position of the thermoelectric conversion unit 20 is deviated.

To the contrary, different from the low-temperature side insulation member 31, the high-temperature side insulation member 32 is composed of aluminum oxide (alumina).

The high-temperature side insulation member 32 of the exemplary embodiment is set in a size slightly larger than the thermoelectric conversion unit 20, and it is desirable that the length of one side of the high-temperature side insulation member 32 is longer than the thermoelectric conversion unit 20 by 1 mm to 5 mm.

### [Configuration of Heat Transfer Unit]

Subsequently, a configuration of the heat transfer unit 40 will be described.

The heat transfer unit 40 includes a low-temperature side heat transfer member 41 and a high-temperature side heat transfer member 42, each of which is made of a cloth material showing a rectangular shape. Of these, the low-temperature side heat transfer member 41 is disposed between the front surface 11a of the base unit 11 and the low-temperature side of the thermoelectric conversion unit 20. On the other hand, the high-temperature side heat transfer member 42 is disposed between the high-temperature side of the thermoelectric conversion unit 20 and the ceiling portion 121 of the lid unit 12.

Both of these low-temperature side heat transfer member 41 and the high-temperature side heat transfer member 42 are composed of a graphite sheet woven from carbon-fiber threads having high thermal conductivity.

The low-temperature side heat transfer member 41 and the high-temperature side heat transfer member 42 are set in the same size as the above-described low-temperature side insulation member 31 and the high-temperature side insulation member 32.

Moreover, it is desirable that the heat transfer unit 40 of the exemplary embodiment is set in a size slightly larger than the insulation unit 30, and the length of one side of the heat transfer unit 40 is longer than the insulation unit 30 by 1 mm to 5 mm. Within the above range, it is possible to secure a contact area between the insulation unit 30 and the heat transfer unit 40, and to transfer sufficient heat to the thermoelectric conversion unit 20 via the insulation unit 30.

As described above, in the thermoelectric conversion device 1 of the exemplary embodiment, in the inner space between the base unit 11 and the lid unit 12, members are disposed from the base unit 11 side in the order of the low-temperature side heat transfer member 41, the low-temperature side insulation member 31, the thermoelectric conversion unit 20, the high-temperature side insulation member 32, the high-temperature side heat transfer member 42 and the lid unit 12 (the ceiling portion 121).

### [Configuration of Thermoelectric Conversion Unit]

Further, a configuration of the thermoelectric conversion unit 20 will be described.

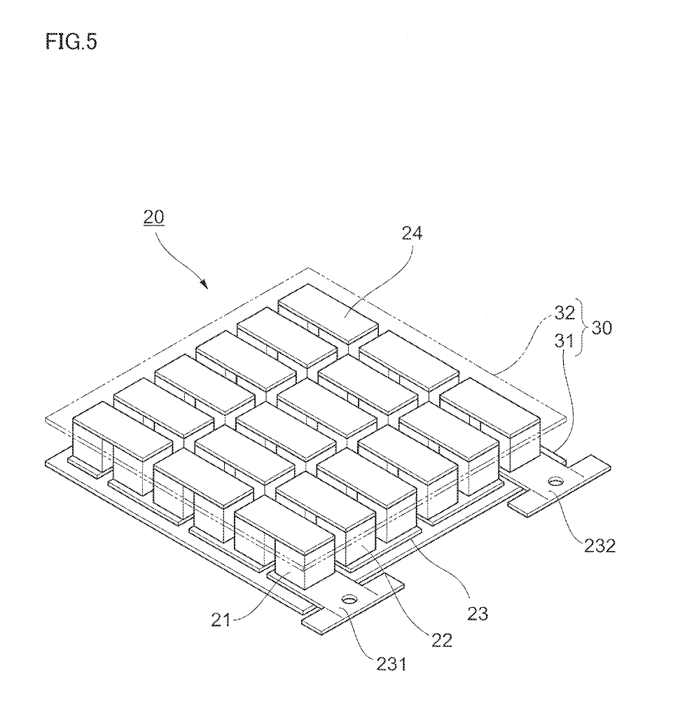

FIG. 5 is a perspective view showing a schematic configuration of a main body of the thermoelectric conversion unit 20 constituting the thermoelectric conversion device 1. In FIG. 5, the insulation unit 30 (the low-temperature side insulation member 31 and the high-temperature side insulation member 32) provided to sandwich the thermoelectric conversion unit 20 is also shown. Hereinafter, descriptions will be given also with reference to FIG. 5 in addition to FIGS. 1 to 4.

The thermoelectric conversion unit 20 of the exemplary embodiment includes plural n-type thermoelectric conversion elements 21 and plural p-type thermoelectric conversion elements 22. Moreover, the thermoelectric conversion unit 20 includes a low-temperature side electrodes 23 provided on the low-temperature side insulation member 31 side and a high-temperature side electrodes 24 provided on the high-temperature side insulation member 32 side, the low-temperature side electrodes 23 and the high-temperature side electrodes 24 connecting the n-type thermoelectric conversion elements 21 and the p-type thermoelectric conversion elements 22 alternately. Further, the thermoelectric conversion unit 20 is provided with the output electric wire 25 including a first output electric wire 251 one end of which is connected to a first extraction electrode 231 constituting the low-temperature side electrode 23 and a second output electric wire 252 one end of which is connected to a second extraction electrode 232 constituting the low-temperature side electrode 23.

In the exemplary embodiment, each of the n-type thermoelectric conversion element 21 and the p-type thermoelectric conversion element 22, as an example of a thermoelectric conversion element, shows a rectangular-parallelepiped shape. Moreover, each of the n-type thermoelectric conversion element 21 and the p-type thermoelectric conversion element 22 is composed of a thermoelectric semiconductor containing Sb (antimony) and including the filled skutterudite structure. Note that it is possible to provide a stress relaxation layer that relaxes a stress to be applied between the n-type thermoelectric conversion element 21 and the corresponding low-temperature side electrode 23 or high-temperature side electrode 24 and between the p-type thermoelectric conversion element 22 and the corresponding low-temperature side electrode 23 or high-temperature side electrode 24 as necessary. Here, in the thermoelectric conversion device 1 of the exemplary embodiment, the low-temperature side electrode 23 contacts the low-temperature side insulation member 31 and the high-temperature side electrode 24 contacts the high-temperature side insulation member 32.

In the thermoelectric conversion unit 20 of the exemplary embodiment, the n-type thermoelectric conversion elements 21 and the p-type thermoelectric conversion elements 22 are arranged in a grid pattern. Then, the n-type thermoelectric conversion elements 21 and the p-type thermoelectric conversion elements 22 are connected in series via the plural low-temperature side electrodes 23 and the plural high-temperature side electrodes 24 to be alternately arranged. In this example, of the n-type thermoelectric conversion elements 21 and the p-type thermoelectric conversion elements 22 connected in series, the first electrode 231 constituting the low-temperature side electrode 23 is connected to the n-type thermoelectric conversion element 21 positioned at one end, and the second extraction electrode 232 constituting the low-temperature side electrode 23 is connected to the p-type thermoelectric conversion element 22 positioned at the other end. One end of the first output electric wire 251 and one end of the second output electric wire 252 are connected to the first extraction electrode 231 and the second extraction electrode 232, respectively.

Here, each of the first output electric wire 251 and the second output electric wire 252 constituting the output electric wire 25 is composed of a conductor portion made of a solid wire of copper covered with an insulation layer made of polyamide. The other end of the first output electric wire 251 is exposed to the outside of the thermoelectric conversion device 1 via the first curved through hole 114 provided to the base unit 11 and the current output terminal 17 attached to the first curved through hole 114. Moreover, the other end of the second output electric wire 252 is exposed to the outside of the thermoelectric conversion device 1 via the second curved through hole 115 provided to the base unit 11 and the current output terminal 17 attached to the second curved through hole 115.

### [Electrical Connection in Thermoelectric Conversion Device]

Here, electrical connection in the thermoelectric conversion device 1 of the exemplary embodiment will be described.

First, in the housing 10, the base unit 11 and the lid unit 12 are electrically connected via the press ring 14 and the twelve pieces screws 15. Moreover, the base unit 11 is electrically insulated from the main body of the thermoelectric conversion unit 20 with the low-temperature side insulation member 31. Further, the lid unit 12 is electrically insulated from the main body of the thermoelectric conversion unit 20 with the high-temperature side insulation member 32. Still further, the base unit 11 is electrically insulated from the output electric wire 25 (the first output electric wire 251 and the second output electric wire 252) with the insulation layer provided to each of the first output electric wire 251 and the second output electric wire 252 and with the elastic member (insulation body) provided inside of each current output terminal 17.

As a result, in the thermoelectric conversion device 1, the housing 10 is electrically insulated from the thermoelectric conversion unit 20 including the output electric wire 25.

### [Airtightness of Thermoelectric Conversion Device]

Subsequently, airtightness of the thermoelectric conversion device 1 of the exemplary embodiment will be described.

First, in the housing 10, the airtight ring 13 is sandwiched all around between the front surface 11a of the base unit 11 and the brim portion 123 of the lid unit 12, and in this state, presses the lid unit 12 against the base unit 11 by use of the press ring 14 and the twelve pieces screws 15. With this, the airtight ring 13 is elastically deformed and the base unit 11 and the lid unit 12 are brought into adhesion via the airtight ring 13.

Moreover, in the base unit 11, the current output terminal 17 is attached to each of the first curved through hole 114 and the second curved through hole 115 that penetrate the front surface 11a and the side surface 11c, and then, the first output electric wire 251 and the second output electric wire 252 penetrate the cylindrical elastic members provided to the inside of the respective current output terminals 17. Here, in the exemplary embodiment, the conductor portions of the first output electric wire 251 and the second output electric wire 252 are composed of the solid wires, not stranded wires, and the insulation layers of the first output electric wire 251 and the second output electric wire 252 are in adhesion with an inner wall of the elastic member.

As a result, in the thermoelectric conversion device 1, airtightness of the inner space, which is formed inside the housing 10 and in which the thermoelectric conversion unit 20 is contained, is maintained. Note that the inner space is filled with Ar (argon) that shows 1 atmospheric pressure at ordinary temperature.

### [Assembling Procedures of Thermoelectric Conversion Device]

This time, assembling procedures of the thermoelectric conversion device 1 of the exemplary embodiment will be described.

Note that kinds of operations to be described hereinafter will be done in an inert gas atmosphere, such as Ar.

First, the first output electric wire 251 is caused to penetrate the first curved through hole 114 of the base unit 11. Subsequently, one end side of the first output electric wire 251 protruded from the side surface 11c of the base unit 11 is inserted into the current output terminal 17. Then, the current output terminal 17 into which the first output electric wire 251 has been inserted is entwisted into the opening portion of the first curved through hole 114 exposed at the side surface 11c of the base unit 11.

Moreover, the second output electric wire 252 is caused to penetrate the second curved through hole 115 of the base unit 11. Subsequently, one end side of the second output electric wire 252 protruded from the side surface 11c of the base unit 11 is inserted into the current output terminal 17. Then, the current output terminal 17 into which the second output electric wire 252 has been inserted is entwisted into the opening portion of the second curved through hole 115 exposed at the side surface 11c of the base unit 11.

Next, of the front surface 11a of the base unit 11, inside the region enclosed by the six protruding portions 112, the low-temperature side heat transfer member 41 is loaded. Next, on the low-temperature side heat transfer member 41, the low-temperature side insulation member 31 is loaded. Then, on the low-temperature side insulation member 31, the thermoelectric conversion unit 20 is loaded to bring the low-temperature side electrodes 23 side into contact with the low-temperature side insulation member 31.

Subsequently, the first extraction electrode 231 provided to the thermoelectric conversion unit 20 and the other end of the first output electric wire 251 protruded from the front surface 11a of the base unit 11 are connected. To describe more specifically, the first extraction electrode 231 is swaged in a state where the first output electric wire 251 is held by the first extraction electrode 231.

Moreover, the second extraction electrode 232 provided to the thermoelectric conversion unit 20 and the other end of the second output electric wire 252 protruded from the front surface 11a of the base unit 11 are connected. To describe more specifically, the second extraction electrode 232 is swaged in a state where the second output electric wire 252 is held by the second extraction electrode 232.

Next, on the high-temperature side electrodes 24 provided to the thermoelectric conversion unit 20, the high-temperature side insulation member 32 is loaded. Next, on the high-temperature side insulation member 32, the high-temperature side heat transfer member 42 is loaded.

Thereafter, of the front surface 11a of the base unit 11, inside the region enclosed by the twelve screw holes 111, the airtight ring 13 is loaded. Moreover, the lid unit 12 is loaded on the front surface 11a side of the base unit 11 in such a manner that the ceiling portion 121 is positioned on the thermoelectric conversion unit 20, the insulation unit 30 and the heat transfer unit 40, and the brim portion 123 is positioned on the airtight ring 13.

Then, on the brim portion 123 in the lid unit 12, the press ring 14 is loaded to cause the twelve screw holes 111 provided to the base unit 11 and the twelve opening portions 141 provided to the press ring 14 to overlap one another. Subsequently, the opening portions 141 provided to the press ring 14 and the respective screw holes 111 provided to the base unit 11 are screwed shut by use of the twelve pieces screws 15.

Thereafter, the two water channel joints 16 are entwisted into the respective both opening portions of the linear through hole 113 exposed at the side surface 11c of the base unit 11.

In this way, the thermoelectric conversion device 1 shown in FIG. 1 is obtained.

Note that, here, the two water channel joints 16 are attached finally; however, attachment of the two water channel joints 16 to the base unit 11 may be carried out any time.

Moreover, attachment of the two current output terminals 17 to the base unit 11 may be carried out any time after the first output electric wire 251 and the second output electric wire 252 are attached to the base unit 11.

### [Operations of Thermoelectric Conversion Device]

Operations of the thermoelectric conversion device 1 of the exemplary embodiment will be described.

Note that, in an initial state, it is assumed that the water for cooling flows through the linear through hole 113 provided to the base unit 11 of the thermoelectric conversion device 1 via the two water channel joints 16.

When the temperature is increased around the ceiling portion 121 of the lid unit 12 by a not-shown heat source, the high-temperature side electrodes 24 of the thermoelectric conversion unit 20 are heated by the lid unit 12 through the high-temperature side heat transfer member 42 and the high-temperature side insulation member 32.

On the other hand, when the temperature is decreased in the base unit 11 by the water flowing through the linear through hole 113, the low-temperature side electrodes 23 of the thermoelectric conversion unit 20 are cooled by the base unit 11 through the low-temperature side heat transfer member 41 and the low-temperature side insulation member 31.

As a result, a large temperature difference (heat flow) is generated between the high-temperature side electrodes 24 and the low-temperature side electrodes 23 of the thermoelectric conversion unit 20, and an electromotive force is developed by performing thermoelectric conversion by each of the n-type thermoelectric conversion elements 21 and p-type thermoelectric conversion elements 22 constituting the thermoelectric conversion unit 20. The electromotive force developed by the thermoelectric conversion unit 20 is extracted to the outside of the thermoelectric conversion device 1 via the first output electric wire 251 connected to the first extraction electrode 231 and the second output electric wire 252 connected to the second extraction electrode 232.

### [Conclusion]

In the thermoelectric conversion device 1, in the state where the airtight ring 13 was sandwiched all around the brim portion 123 between the front surface 11a of the base unit 11 and the brim portion 123 of the lid unit 12, the brim portion 123 of the lid unit 12 was pressed against the base unit 11 side by use of the press ring 14 and the twelve pieces screws 15, and thereby the lid unit 12 was fixed to the base unit 11. In other words, in the exemplary embodiment, the base unit 11 and the lid unit 12 were not directly fixed by use of the plural screws 15, but indirectly fixed by use of the press ring 14 and the plural screws 15.

At this time, in the inner space in the thermoelectric conversion device 1 where the thermoelectric conversion unit 20 is disposed, that is, in a region enclosed by the front surface 11a of the base unit 11, the ceiling portion 121 and the inner side of the side wall portion 122 of the lid unit 12 and the airtight ring 13, the ceiling portion 121 presses the thermoelectric conversion unit 20 against the front surface 11a side of the base unit 11 via the heat transfer unit 40 (the low-temperature side heat transfer member 41 and the high-temperature side heat transfer member 42) and the insulation unit 30 (the low-temperature side insulation member 31 and the high-temperature side insulation member 32).

This makes it possible to increase the degree of adhesion between the low-temperature side of the thermoelectric conversion unit 20 (the low-temperature side electrodes 23 side) and the base unit 11 via the low-temperature side insulation member 31 and the low-temperature side heat transfer member 41. Moreover, it is possible to increase the degree of adhesion between the high-temperature side of the thermoelectric conversion unit 20 (the high-temperature side electrodes 24 side) and the lid unit 12 via the high-temperature side insulation member 32 and the high-temperature side heat transfer member 42.

Therefore, by adopting such a configuration, it becomes possible to improve the thermoelectric conversion efficiency in the thermoelectric conversion device 1.

Moreover, in the thermoelectric conversion device 1 of the exemplary embodiment, the pressure applied to the thermoelectric conversion unit 20 and the pressure distribution were able to be adjusted by changing each of entwisting amounts of the twelve pieces screws 15 to carry out positioning and fixing of the base unit 11 and the lid unit 12 via the press ring 14.

This makes it possible to suppress imbalance in the load applied to the thermoelectric conversion unit 20 and the load applied to each of the thermoelectric conversion elements (the plural n-type thermoelectric conversion elements 21 and the plural p-type thermoelectric conversion elements 22) constituting the thermoelectric conversion unit 20, and accordingly, it becomes possible to suppress decrease in the thermoelectric conversion efficiency caused by imbalance in the load and damage in part of the thermoelectric conversion elements.

Moreover, in the thermoelectric conversion device 1, the ceiling portion 121 of the lid unit 12 constituting the housing 10 was formed in a circular shape.

This makes it possible to further suppress imbalance in the load provided to the thermoelectric conversion unit 20 from the lid unit 12, as compared to the case of adopting, for example, a configuration in which the ceiling portion 121 is formed in a polygonal shape and corner portions are provided to the ceiling portion 121.

Moreover, in the thermoelectric conversion device 1, the current output terminals 17 were attached to the respective opening portions on the side surface 11c side of the first curved through hole 114 and the second curved through hole 115 penetrating the front surface 11a and the side surface 11c of the base unit 11. Then, by using the solid wire of copper covered with the insulation layer as the first output electric wire 251 and the second output electric wire 252 provided to penetrate the first curved through hole 114 and the second curved through hole 115, respectively, airtightness in contact portions between the first output electric wire 251, the second output electric wire 252 and the respective current output terminals 17 was increased.

This makes it possible to increase airtightness of the inner space in the thermoelectric conversion device 1 where the thermoelectric conversion unit 20 is disposed. Then, by filling the inner space with Ar, it is possible to suppress deterioration of the thermoelectric conversion unit 20 (the n-type thermoelectric conversion elements 21 and the p-type thermoelectric conversion elements 22) due to temperature changes (heat deterioration).

Moreover, in the thermoelectric conversion device 1, the high-temperature side insulation member 32 provided on the lid unit 12 side as viewed from the thermoelectric conversion unit 20 was composed of aluminum oxide (alumina), and the low-temperature side insulation member 31 provided on the base unit 11 side as viewed from the thermoelectric conversion unit 20 was composed of aluminum nitride. Here, aluminum nitride has high thermal conductivity but is likely to cause gas separation in high-temperature environment, as compared to aluminum oxide, and aluminum oxide has low thermal conductivity but is less likely to cause gas separation in high-temperature environment, as compared to aluminum nitride.

Therefore, in the exemplary embodiment, it is possible to suppress generation of gas from the high-temperature side insulation member 32 due to temperature rises, while securing the insulation property between the housing 10 and the thermoelectric conversion unit 20 and the thermal conductivity from the housing 10 to the thermoelectric conversion unit 20 by use of the insulation unit 30. As a result, it is possible to suppress deterioration of the thermoelectric conversion unit 20 (the n-type thermoelectric conversion elements 21 and the p-type thermoelectric conversion elements 22) due to existence of a gas other than Ar (such as oxygen) in the inner space (heat deterioration).

Here, in the thermoelectric conversion device 1, whereas a hard ceramic material was used for the insulation unit 30 (the low-temperature side insulation member 31 and the high-temperature side insulation member 32) brought into contact with the thermoelectric conversion unit 20, a soft graphite sheet was used for the heat transfer unit 40 (the low-temperature side heat transfer member 41 and the high-temperature side heat transfer member 42) brought into contact with the insulation unit 30 and the base unit 11 or the lid unit 12.

This allows the soft heat transfer unit 40 to function as a buffer layer for the thermoelectric conversion unit 20 and the insulation unit 30 made of the hard and brittle material, and thereby it is possible to suppress damage to these thermoelectric conversion unit 20 and insulation unit 30.

In the thermoelectric conversion device 1 of the exemplary embodiment, with changes in surrounding temperature, the base unit 11 and the lid unit 12 constituting the housing 10 thermally expand or thermally contract. At this time, the distance from the front surface 11a of the base unit 11 to the inner wall surface of the ceiling portion 121 of the lid unit 12 (the height of the inner space) varies in some cases.

In contrast thereto, in the thermoelectric conversion device 1 of the exemplary embodiment, the low-temperature side heat transfer member 41, the low-temperature side insulation member 31 and the thermoelectric conversion unit 20 were disposed inside the six protruding portions 112 provided to the front surface 11a of the base unit 11.

Consequently, for example, even in a case where the pressure applied to the thermoelectric conversion unit 20 is reduced with increase in height of the inner space due to temperature changes, it is possible to suppress positional deviation of the thermoelectric conversion unit 20 in a horizontal direction of the front surface 11a.

Moreover, in the thermoelectric conversion device 1 of the exemplary embodiment, since the back surface 11b of the base unit 11 positioned on the low-temperature side is flat, a fin, a metal plate or the like for cooling can be attached with ease.

Moreover, in the thermoelectric conversion device 1, as was clear from FIGS. 1 and 5, on the side surface 11c of the base unit 11, the first curved through hole 114, the second curved through hole 115 and the non-through hole 116 were unevenly disposed on one side (the lower side in FIG. 4) as viewed from the linear through hole 113. In other words, the opening portions were not provided on the other side (the upper side in FIG. 4) of the side surface 11c of the base unit 11.

This makes it possible to increase the degree of freedom about the position where the thermoelectric conversion device 1 is to be attached.

### [Others]

Note that, in the exemplary embodiment, the base unit 11 and the lid unit 12 were electrically connected via the press ring 14 and the twelve pieces screws 15; however, the present invention is not limited thereto. For example, the base unit 11 may be electrically insulated from the lid unit 12 by composing at least one of the press ring 14 and the screws 15 of an insulating material.

Moreover, in the exemplary embodiment, the twelve pieces screws 15 were used; however, the number of screws 15 is not limited thereto.

Further, in the exemplary embodiment, description was given by taking the case as an example, in which the thermoelectric semiconductor containing Sb (antimony) and including the filled skutterudite structure was used as the thermoelectric conversion element; however, the present invention is not limited thereto, and is applicable to a case in which a thermoelectric conversion element using any of various kinds of thermoelectric semiconductors as a material is adopted.

Still further, in the exemplary embodiment, description was given by taking the case in which the single thermoelectric conversion unit 20 was disposed between the base unit 11 and the lid unit 12 as an example; however, plural thermoelectric conversion units 20 may be disposed there.

The foregoing description of the present exemplary embodiment of the present invention has been provided for the purposes of illustration and description. It is not intended to be exhaustive or to limit the invention to the precise forms disclosed. Obviously, many modifications and variations will be apparent to practitioners skilled in the art. The present exemplary embodiment was chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A thermoelectric conversion device comprising:
a thermoelectric conversion unit that includes thermoelectric conversion elements converting thermal energy caused by temperature difference between a high-temperature side and a low-temperature side of the thermoelectric conversion unit into electric energy;
a loading member that is loaded with the low-temperature side of the thermoelectric conversion unit;
a covering member that covers the high-temperature side of the thermoelectric conversion unit loaded on the loading member;
a sandwiching member that is provided over an entire circumference of an outside of periphery of the thermoelectric conversion unit loaded on the loading member and sandwiches the covering member between the sandwiching member and the loading member; and
a positioning member that positions the covering member with respect to the loading member and sandwiches the thermoelectric conversion unit between the loading member and the covering member to position the thermoelectric conversion unit by fixing the sandwiching member to the loading member.

2. The thermoelectric conversion device according to claim 1, wherein
the loading member includes a front surface that is loaded with the thermoelectric conversion unit, a back surface that is an opposite side of the front surface and a side surface positioned between the front surface and the back surface, and
the loading member is provided with a through hole, one end of which is provided to the front surface and the other end of which is provided to the side surface, and inside of which an electric wire for extracting current generated in the thermoelectric conversion unit to an outside penetrates, and another through hole, one and the other ends of which are provided to the side surface, and inside of which a liquid for cooling the low-temperature side of the thermoelectric conversion unit passes.

3. The thermoelectric conversion device according to claim 2, wherein, when the loading member is provided with a plurality of the through holes, in the loading member, the plurality of through holes are disposed only at one side of the side surface of the loading member as viewed from the another through hole.

4. The thermoelectric conversion device according to claim 1, further comprising: an airtight member that is provided between the loading member and a portion of the covering member which is sandwiched by the sandwiching member, the airtight member having elasticity and being in contact with the loading member and the covering member over an entire circumference, to increase airtightness of an inner space formed by the loading member and the covering member for containing the thermoelectric conversion unit.

5. The thermoelectric conversion device according to claim 1, further comprising:
a low-temperature side insulation member that is composed of aluminum nitride and disposed between the loading member and the low-temperature side of the thermoelectric conversion unit to electrically insulate the loading member from the thermoelectric conversion unit; and
a high-temperature side insulation member that is composed of aluminum oxide and disposed between the covering member and the high-temperature side of the thermoelectric conversion unit to electrically insulate the covering member from the thermoelectric conversion unit.

6. The thermoelectric conversion device according to claim 1, wherein the loading member is composed of an aluminum alloy and the covering member and the sandwiching member are composed of a stainless steel.

7. The thermoelectric conversion device according to claim 1, wherein, on a loading surface in the loading member to be loaded with the thermoelectric conversion unit, a plurality of protruding portions are provided to positions enclosing around the loaded thermoelectric conversion unit.
